(19) United States
(12) Patent Application Publication
(10) Pub. No.: US 2026/0165082 A1
(43) Pub. Date: Jun. 11, 2026

(54) CURVED ELECTROSTATIC CHUCKS

(71) Applicant: Applied Materials, Inc., Santa Clara, CA (US)

(72) Inventors: Jian LI, Fremont, CA (US); Anand VASUDEV, San Francisco, CA (US); Ganesh BALASUBRAMANIAN, Fremont, CA (US); Juan C. ROCHA, San Carlos, CA (US); Ankit Atul GORATELA, San Jose, CA (US)

(21) Appl. No.: 18/971,185

(22) Filed: Dec. 6, 2024

(51) Int. Cl. H01L 21/683; H01J 37/32

(52) U.S. Cl. CPC H10P 72/722; H01J 37/32724; H01J 2237/2007

(57) ABSTRACT

Embodiments described herein generally relate to substrate processing apparatuses. More specifically, embodiments described herein relate to substrate support designs used to limit or prevent damage to the back side of a substrate. In at least one embodiment, a substrate support assembly is provided. The substrate support assembly includes a substrate support body including a curved surface having a curve profile, the curve profile having a curve depth of about 0.5 mm or greater, and an electrode disposed in the substrate support body below the curved surface, the electrode being curved to substantially match the curve profile of the curved surface.

### BACKGROUND

### Field

Embodiments of the present disclosure generally relate to processing systems used for processing semiconductors. More particularly, embodiments described herein relate to substrate supports used in processing systems to limit or prevent damage to the backside of a substrate when the substrate is supported by the substrate support.

### Description of the Related Art

Substrates are placed on substrate supports during a variety of processes, such as during semiconductor processing. The substrates can be susceptible to damage (e.g., mechanical damage) during handling and processing of the substrates. One area that is often damaged is the backside of the substrate. For example, substrates are often supported during processing by positioning the backside of the substrate or a portion of the backside of the substrate on a substrate support. The mechanical contact between the backside of the substrate and the supporting surface(s) of the substrate support can result in damage to the backside of the substrate.

For many processes, it is important for a substrate, such as a semiconductor wafer, to remain clamped in place on the substrate support during processing. However, bowing of the wafer can cause significant problems in maintaining this clamped state. In particular, large bows can create sufficient distance between the substrate surface and the substrate support surface such that electrostatic forces generated by conventional electrostatic chucking techniques are not sufficient to overcome the distance caused by the bowing. High chucking voltages may be used to flatten the substrate, however, high chucking voltages may cause arcing and wafer damage due to the stress applied to the substrate whilst being flattened. This damage can diminish the performance of the device that is ultimately manufactured from the substrate or undesirably alter subsequent processes performed on the substrate, such as causing non-uniformities during subsequent deposition or etching processes.

Accordingly, there is a need to improve chucking of bowed substrates and limit and/or prevent damage to the backside of the substrates during processing and handling of the substrates.

### SUMMARY

Embodiments described herein generally relate to substrate processing apparatuses. More specifically, embodiments described herein relate to substrate support designs.

In at least one embodiment, a substrate support assembly is provided. The substrate support assembly includes a substrate support body including a curved surface having a curve profile, the curve profile having a curve depth of about 0.5 mm or greater, and an electrode disposed in the substrate support body below the curved surface, the electrode being curved to substantially match the curve profile of the curved surface.

In at least one other embodiment, a processing system is provided. The processing system includes a processes chamber including a chamber body disposed around an interior volume, a substrate support assembly positioned in the interior volume, and a showerhead disposed above the substrate support assembly. The substrate support assembly including a substrate support body including a first curved surface having a first curve profile, and an electrode disposed in the substrate support body below the first curved surface, the electrode being curved to substantially match the first curve profile of the first curved surface. The showerhead including a second curved surface having a second curve profile.

In at least one other embodiment, a processing system is provided. The processing system including a process chamber including, a chamber body disposed around an interior volume, a substrate support assembly positioned in the interior volume, and a showerhead disposed above the substrate support assembly. The substrate support assembly including a substrate support body including a first curved surface having a first curve profile, and an electrode disposed in the substrate support body below the first curved surface, the electrode being curved. The showerhead includes a second curved surface having a second curve profile. The processing system additionally includes a bowed substrate positioned on the first curved surface of the substrate support body, the bowed substrate comprising a curve having a third curve profile.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and the disclosure may admit to other equally effective embodiments.

FIG. 1 is a cross-sectional view of a processing system, according to some embodiments.

FIG. 2 is a cross-sectional view of the substrate support body from FIG. 1, according to some embodiments.

FIG. 3 is a cross-sectional view of an alternative substrate support body that can be used as part of the substrate support assembly from FIG. 1, according to some embodiments.

FIG. 4 is a simplified cross-sectional view of an alternative showerhead and substrate support body that can be implemented in the processing system from FIG. 1, according to some embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to processing systems used for processing substrates, such as semiconductor substrates. More particularly, embodiments described herein relate to substrate supports having a curved surface profile and an embedded curved electrode that improve chucking of highly bowed substrates. The improved substrate supports can be used in processing systems to limit or prevent damage to the back side of the substrate when the substrate is supported by the substrate support.

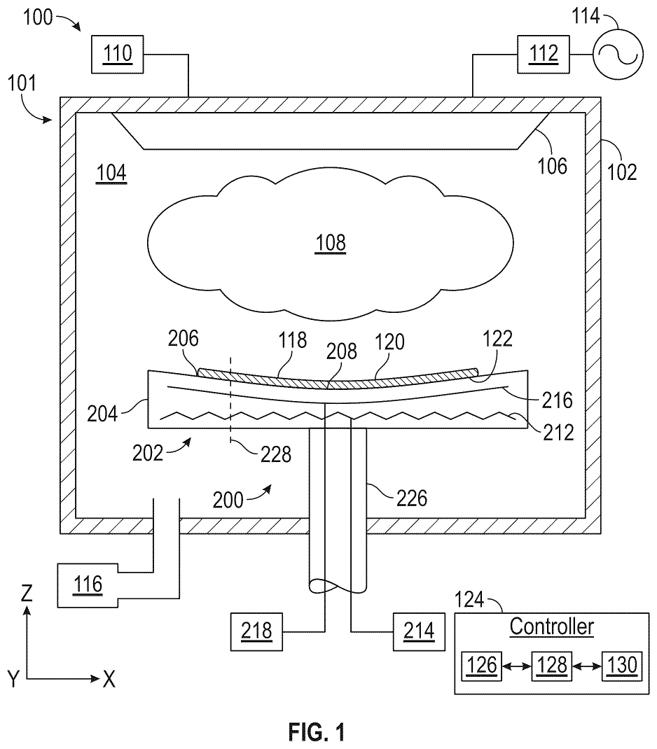

FIG. 1 shows a processing system 100, according to some embodiments. The processing system 100 includes a process chamber 101, a gas supply system 110, an energy source 114, a vacuum pump 116, and a controller 124. The process chamber 101 includes a chamber body 102 enclosing an interior volume 104. In at least one embodiment, the process chamber 101 is a deposition chamber. In other embodiments, the process chamber 101 may be configured to perform other processes, such as an etching process.

The process chamber 101 may include a showerhead 106 for directing process or cleaning gases into the interior volume 104 of the process chamber 101. The vacuum pump 116 can be used to exhaust gases from the interior volume 104 and to maintain a specified pressure in the interior volume 104 during processing.

In some embodiments, which can be combined with other embodiments, the energy source 114 is a radio frequency (RF) power source. In some of these embodiments, the processing system 100 is configured to generate a plasma 108 of the process or cleaning gases in the interior volume 104 of the process chamber 101 by supplying RF power from the energy source 114 to the showerhead 106. The energy source 114 can be electrically coupled to the showerhead 106 through a matching circuit 112.

The process chamber 101 further includes a substrate support assembly 200 having a substrate support body 202 positioned in the interior volume 104. The substrate support assembly 200 further includes a shaft 226 coupled to the substrate support body 202. In some embodiments, the shaft 226 can be coupled to an actuator (not shown), which can rotate the shaft 226 during processing. A substrate 118 can be positioned on the substrate support body 202. The substrate 118 is shown with an exaggerated sag in the Z-direction, such that the substrate has an exaggerated concave bow, or curve. In at least some embodiments, the substrate 118 may be a bowed substrate having a concave curve or a convex curve. The substrate 118 may have a curve profile. The substrate 118 can include a front side 120 and a back side 122. The rotation of the shaft 226 can be used to rotate the substrate support body 202 and the substrate 118 positioned on the substrate support body 202 during processing. The rotation of the substrate 118 can improve process uniformity for the process (e.g., deposition) being performed on the substrate 118. In some embodiments, which can be combined with other embodiments, the substrate support body 202 can be formed of materials that are electrically insulating while also being thermally conductive, such as aluminum oxide or aluminum nitride. In other embodiments, which can be combined with other embodiments, the substrate support body 202 can be formed of materials that have low thermal conductivity, such as silicon nitride.

In at least some embodiments, the substrate support body 202 may include an outer rim 204 disposed around an inner portion 208. The inner portion 208 includes a first surface 206 extending inwardly from the outer rim 204. The first surface 206 may also be more generally referred to as a substrate supporting structure. The substrate 118 can be positioned on the first surface 206 during processing.

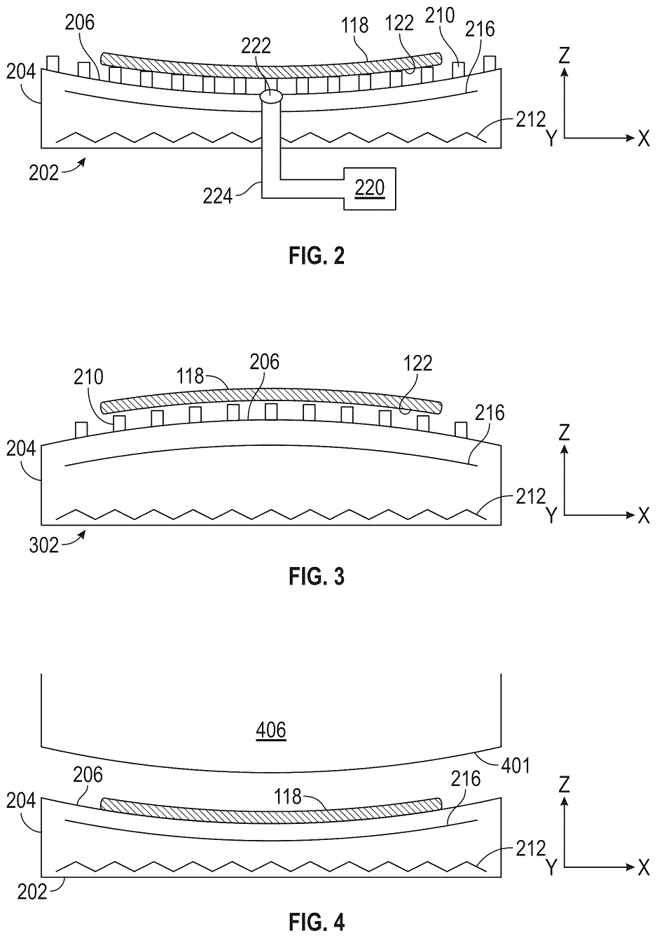

The first surface 206 may be a curved surface. In at least some embodiments, the first surface 206 may gradually slope from the outer rim 204 to a center point of the inner portion 208, forming a curved surface having a curve depth of about 0.5 mm or greater, such as about 0.5 mm to about 10 mm, about 0.5 mm to about 4 mm, about 0.6 mm to about 3.5 mm, about 0.8 mm to about 3 mm, or about 1 mm to 2 mm. The curve depth may be defined as the difference in height between the outer rim 204 and the center point of the inner portion 208. In at least some embodiments, the first surface 206 may have a concave curve profile as shown in FIGS. 1-2 or a convex curve profile as shown in FIG. 3. The curve profile of the first surface 206 is configured to substantially match the contour or curve of the substrate 118. In at least some embodiments, the curve profile of the first surface 206 may be substantially the same as or slightly less than the curve of the substrate 118 positioned on the substrate support body 202.

In at least some embodiments, the curve profile of the first surface 206 reduces the variability of the distance between the back side 122 of the substrate 118 and the first surface 206. This reduction in the variability of the distance reduces the strain placed on the substrate 118 during electrostatic or vacuum chucking, thus limiting or preventing damage to the back side 122 of the substrate 118.

The substrate support assembly 200 can further include an electrode 216 positioned inside the substrate support body 202. The electrode 216 may be connected to an electrical power source 218. In at least some embodiments, the electrode 216 is an electrode mesh including one or more RF electrodes and one or more direct current (DC) electrodes. The electrical power source 218 may supply both DC and RF power to the electrode 216. The electrode 216 may be a curved electrode. In at least some embodiments, the electrode 216 is curved to substantially match the curve profile of the first surface 206, such that the distance between the electrode 216 and the first surface 206 is consistent throughout the substrate support body. In at least some embodiments, the distance between the electrode 216 and the first surface 206 may be about 0.5 mm to about 3 mm, such as about 1 mm to about 2.5 mm, about 1 mm to about 2 mm, about 1 mm to about 1.5 mm, or about 1 mm. When the substrate 118 is chucked, whether by electrostatic or vacuum chucking, the distance between the curved electrode 216 and the back side 122 of the substrate 118 is consistent from the center to the edge of the substrate 118. This reduction in the variability of the distance between the back side 122 of the substrate 118 and the curved electrode 216 improves the uniformity of the RF impedance between the curved electrode 216 and the substrate 118 across the substrate 118 from center to edge, which improves the uniformity of plasma intensity across the substrate 118 during processes, such as plasma depositions. The reduction in the variability of the distance also improves the uniformity of the heat transfer from the substrate support body 202 to the substrate 118 across the substrate 118 from center to edge, which improves the uniformity of the temperature across the substrate 118 during processes, such as plasma depositions. The improvement of plasma intensity and temperature uniformity improves the uniformity of the process being performed, such as an improvement in deposition thickness across the substrate 118 from the center of the substrate 118 to the edge of the substrate 118.

In at least some embodiments, the electrode 216 may be a chucking electrode, which secures the substrate 118 to the first surface 206 of the substrate support body 202 by providing a voltage between the substrate 118 and the electrode 216. The voltage between the substrate 118 and the electrode 216 results in an electrostatic chucking force therebetween. In at least some embodiments, the electrical power source is a DC power source, which may provide a DC chucking voltage of about 100 volts to about 1,000 volts to the electrode 216. In at least some embodiments, when the substrate 118 is electrostatically chucked, the curve profile of the first surface 206 reduces the voltage necessary to chuck the substrate 118. For example, in at least one embodiment, a bowed wafer, such as substrate 118, may be electrostatically chucked to the curved first surface 206 by applying a DC chucking voltage of about 100 volts to about 1,000 volts to the electrode 216. In contrast, chucking a similarly bowed substrate 118 to a flat surface substrate support may be achieved using a DC chucking voltage of about 2,000 volts.

The substrate support assembly 200 can further include a heater 212 (e.g., a resistive heater) positioned inside the substrate support body 202. The heater 212 can be connected to an electrical power source 214. The heater 212 can be configured to heat the substrate 118 during one or more processes, such as one or more depositions, when electrical power is provided to the heater 212 from the electrical power source 214. In at least some embodiments, the electrode 216 is positioned at first vertical location in the substrate support body 202 along the vertical axis 228, and the heater 212 is positioned at a second vertical location in the substrate support body 202 along the vertical axis 228. In at least some embodiments, the heater 212 is disposed below the electrode 216. In at least some embodiments, the heater 212 may be curved to substantially match the curve of the electrode 216 and/or the curve profile of the first surface 206, such that the distance between the heater 212 and the first surface 206 is consistent throughout the substrate support body.

The processing system 100 may also include the controller 124 for controlling processes performed by the processing system 100. The controller 124 can be any type of controller used in an industrial setting, such as a programmable logic controller (PLC). The controller 124 includes a processor 128, a memory 126, and input/output (I/O) circuits 130. The controller 124 can further include one or more of the following components (not shown), such as one or more power supplies, clocks, communication components (e.g., network interface card), and user interfaces typically found in controllers for semiconductor equipment.

The memory 126 can include non-transitory memory. The non-transitory memory can be used to store the programs and settings described below. The memory 126 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

The processor 128 is configured to execute various programs stored in the memory 126, such as deposition processes, etching processes, cleaning processes, etc. During execution of these programs, the controller 124 can communicate to I/O devices through the I/O circuits 130. For example, during execution of these programs and communication through the I/O circuits 130, the controller 124 can control outputs, such as energizing the energy source 114, adjusting the voltage applied to the electrode 216, or changing the position of valves (not shown) to send process gases to the interior volume 104 of the process chamber 101. The memory 126 can further include various operational settings used to control the processing system 100. For example, the settings can include durations of time indicating how long the different valves remain open or closed during different depositions or other processes.

FIG. 2 is a cross-sectional view of the substrate support body 202 from FIG. 1, according to at least one embodiment. The view in FIG. 2 shows additional detail of the substrate support body 202.

The substrate support body 202 can additionally include a plurality of dimples 210 extending upward from the first surface 206 of the inner portion 208. For clarity of illustration, the dimples 210 are not shown in FIG. 1. In some embodiments, the dimples 210 can have a height in the Z-direction from about 10 micron to about 25 micron, such as about 10 micron to about 20 micron, or about 15 micron. In at least some embodiments, the dimples 210 have a consistent height (e.g., the distance from the first surface 206 to the top of the dimples 210) across the first surface 206. In other embodiments, the dimples 210 may vary in height across the first surface 206 to better fit the curve of the substrate 118.

The dimples 210 are configured to support the substrate 118 while having a small surface area in the XY plane, so that only a small surface area of the back side 122 of the substrate 118 is in contact with the substrate support body 202. The dimples 210 are only one example of supporting structures that can be used to support the back side 122 of the substrate 118 and numerous other structures can be used, such as bumps, ridges, etc.

In some embodiments, which can be combined with other embodiments, the dimples 210 can be polished to reduce the amount of damage to the back side 122 of the substrate 118 in the event there is contact between the back side 122 of the substrate and the dimples 210. For example, in at least one embodiment, the dimples 210 having a roughness average (Ra) of Ra 30 μin can be polished to a roughness from about Ra 2 μin to about Ra 6 μin, such as about Ra 4 μin.

In at least some embodiments, which can be combined with other embodiments, the substrate support body 202 further includes one or more apertures 222 in the first surface 206 connected to a vacuum source 220 via a conduit 224. The vacuum source 220 may apply a holding force, such as a suction or vacuum force, to the substrate 118, vacuum chucking the substrate 118 to the first surface 206 of the substrate support body 202. In at least some embodiments, the curve profile of the first surface 206 improves the efficiency of the vacuum chucking as the curve profile of the first surface 206 reduces the variability of the distance between the back side 122 of the substrate 118 and the first surface 206. This reduction in the variability of the distance reduces potential air gaps between the back side 122 of the substrate 118 and the first surface 206.

FIG. 3 is a cross-sectional view of an alternative substrate support body 302 that can be used as part of the substrate support assembly 200 from FIG. 1, according to some embodiments. The substrate support body 302 is the same as the substrate support body 202 described above except that the first surface 206 of the substrate support body 302 has a convex curve profile configured to support the substrate 118 having a convex bow or curve. In at least some embodiments, the first surface 206 may gradually slope upward from the outer rim 204 to a center point of the inner portion 208, forming a convex curved surface having a curve depth of about 0.5 mm or greater, such as about 0.5 mm to about 10 mm, about 0.5 mm to about 4 mm, about 0.6 mm to about 3.5 mm, about 0.8 mm to about 3 mm, or about 1 mm to 2 mm. In at least some embodiments, the electrode 216 may have a convex curve to match the convex curve profile of the first surface 206.

FIG. 4 is a simplified cross-sectional view of an alternative showerhead and substrate support body configuration that can be implemented in the processing system 100 from FIG. 1, according to some embodiments. In at least some embodiments, the showerhead 406 includes a surface 401 disposed over the substrate support assembly 200. The surface 401 may be a curved surface having a convex curve profile or a concave curve profile. In at least some embodiments, the curve of the surface 401 is configured to complement the curve profile of the first surface 206 of the substrate support body 202, such that the distance between the surface 401 of the showerhead 406 and the first surface 206 of the substrate support body is consistent from center to edge. For example, in some embodiments, the first surface 206 of the substrate support body 202 may have a concave curve profile having a curve depth of about 0.5 mm to about 4 mm, and the surface 401 of the showerhead may have a convex curve profile having a similar curve depth to the first surface 206.

In at least some embodiments, the showerhead 406 may be disposed about 4 mm to about 25 mm above the substrate 118, such as about 4 mm to about 20 mm, about 5 mm to about 15 mm, or about 10 mm. The curve of the surface 401 may be configured such that the distance between the surface 401 of the showerhead 406 and the substrate 118 is consistent from the center of the substrate 118 to the edge of the substrate 118. The consistent distance between the surface 401 of the showerhead 406 and the substrate 118 improves the uniformity of plasma intensity across the substrate 118 during processes, which improves the uniformity of the process being performed, such as an improvement in deposition thickness across the substrate 118 from the center of the substrate 118 to the edge of the substrate 118.

Overall, the present disclosure provides improved designs for substrate supports for substrate processing apparatuses. Designs disclosed here in generally include substrate supports having a curved surface profile and an embedded curved electrode that improve chucking of highly bowed substrates. The improved substrate supports can be used in processing systems to limit or prevent damage to the back side of the substrate when the substrate is supported by the substrate support. In at least some embodiments, the curved surface profile and an embedded curved electrode reduce the variability of the distance between the substrate, the surface of the substrate support, and the curved electrode, thus improving chucking efficiency, RF impedance uniformity, and heat transfer uniformity. In at least some other embodiments, a showerhead having a curved surface that complements the curved surface profile of the substrate support may be implemented to reduce the variability of the distance between the substrate and the showerhead from the center of the substrate to the edge of the substrate, thus improving the uniformity of plasma intensity across the substrate.

While the foregoing is directed to specific implementations, other and further embodiments may be devised without departing from the basic scope thereof. The present disclosure also contemplates that one or more aspects of the implementations described herein may be substituted in for one or more of the other aspects described. The scope of the disclosure is determined by the claims that follow.

Certain implementations and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A substrate support assembly comprising:
a substrate support body comprising a curved surface having a curve profile, the curve profile having a curve depth of about 0.5 mm or greater; and
an electrode disposed in the substrate support body below the curved surface, the electrode being curved to substantially match the curve profile of the curved surface.

2. The substrate support assembly of claim 1, wherein the curve profile of the curved surface substantially matches a curve of a substrate positioned on the substrate support body.

3. The substrate support assembly of claim 1, wherein the substrate support body further comprises a plurality of dimples extending upward from the curved surface.

4. The substrate support assembly of claim 1, wherein the substrate support body comprises one or more of aluminum nitride, aluminum oxide, and silicon nitride.

5. The substrate support assembly of claim 1, wherein the electrode comprises a mesh.

6. The substrate support assembly of claim 5, wherein the mesh comprises one or more radio frequency (RF) electrodes and one or more direct current (DC) electrodes.

7. The substrate support assembly of claim 1, further comprising a heater disposed in the substrate support body.

8. The substrate support assembly of claim 1, wherein the substrate support assembly comprises an electrostatic chuck.

9. A processing system comprising:
a process chamber comprising:
a chamber body disposed around an interior volume;
a substrate support assembly positioned in the interior volume, the substrate support assembly comprising:
a substrate support body comprising a first curved surface having a first curve profile; and
an electrode disposed in the substrate support body below the first curved surface, the electrode being curved to substantially match the first curve profile of the first curved surface; and
a showerhead disposed above the substrate support assembly, the showerhead comprising a second curved surface having a second curve profile.

10. The processing system of claim 9, wherein the first curve profile of the first curved surface is a concave curve profile.

11. The processing system of claim 10, wherein the concave curve profile of the first curved surface substantially matches a curve of a bowed substrate positioned on the substrate support body.

12. The processing system of claim 9, wherein the first curve profile of the first curved surface is a convex curve profile.

13. The processing system of claim 9, wherein the second curve profile of the second curved surface complements the first curve profile of the first curved surface.

14. The processing system of claim 9, further comprising a heater disposed in the substrate support body.

15. The processing system of claim 14, wherein the heater is curved to substantially match the curve of the electrode.

16. The processing system of claim 9, wherein the first curve profile has a curve depth of about 0.5 mm to about 4 mm.

17. The processing system of claim 9, wherein the substrate support body further comprises a plurality of dimples extending upward from the first curved surface.

18. A processing system comprising:
a process chamber comprising:
a chamber body disposed around an interior volume;
a substrate support assembly positioned in the interior volume, the substrate support assembly comprising:
a substrate support body comprising a first curved surface having a first curve profile
an electrode disposed in the substrate support body below the first curved surface, the electrode being curved; and
a showerhead disposed above the substrate support assembly, the showerhead comprising a second curved surface having a second curve profile; and
a bowed substrate positioned on the first curved surface of the substrate support body, the bowed substrate comprising a curve having a third curve profile.

19. The processing system of claim 18, wherein the first curve profile of the first curved surface substantially matches the third curve profile of the bowed substrate positioned on the substrate support body.

20. The processing system of claim 18, wherein the second curve profile of the second curved surface complements the first curve profile of the first curved surface.
